(19) United States
(12) Patent Application Publication
(10) Pub. No.: US 2011/0012696 A1
(43) Pub. Date: Jan. 20, 2011

(54) SWITCHED ACOUSTIC WAVE RESONATOR FOR TUNABLE FILTERS

(75) Inventor: Carl Filip Erik Skarp, Lund (SE)

Correspondence Address: HARRITY & HARRITY, LLP, 11350 RANDOM HILLS ROAD, SUITE 600, FAIRFAX, VA, 22030, US

(73) Assignee: Sony Ericsson Mobile Communications AB, Lund (SE)

(21) Appl. No.: 12/505,867

(22) Filed: Jul. 20, 2009

(51) Int. Cl. H03H 9/64

(52) U.S. Cl. 333/195; 333/188

(57) ABSTRACT

A filter for a mobile terminal may include a substrate through which to propagate an acoustic wave; a resonator on a surface of the substrate, the resonator including a first segment and a second segment, the first segment operatively connected to an electrical port; and a switch unit, where the switch unit connects the first segment and the second segment when the switch unit is in one position, the connected first segment and second segment being configured to generate, through the substrate, an acoustic wave at a first frequency, and where the switch unit separates the first segment and the second segment when the switch unit is in another position, the separated first segment being configured to generate, through the substrate, an acoustic wave at a second frequency.

### BACKGROUND

Mobile communications are divided among various radio frequency bands to support current and planned technologies. Frequency bands may also be divided among regions, such that different wireless service providers may use different bands in different regions. Some mobile devices, such as multi-band or multi-mode mobiles phones, have been designed to operate in more than one frequency band. Optimally, these mobile devices can share components. However, sharing of components presents a challenge for mobile devices that operate in multiple frequencies. To support each band, mobile devices typically include certain dedicated components for each frequency band, which may increase the size and architectural complexity of the mobile device. As a particular example, a multi-mode architecture for a mobile device supporting quad-band EDGE, quad-band UMTS, and single-band LTE together with 4-band diversity can require ten or more separate filters.

### SUMMARY

According to one implementation, a filter for a mobile terminal may include a substrate through which to propagate an acoustic wave; a resonator on a surface of the substrate, where the resonator may include a first segment and a second segment, and the first segment may operatively connect to an electrical port; and a switch unit, where the switch unit may connect the first segment and the second segment when the switch unit is in one position, the connected first segment and second segment may be configured to generate, through the substrate, an acoustic wave at a first frequency, and where the switch unit may separate the first segment and the second segment when the switch unit is in another position, the separated first segment may be configured to generate, through the substrate, an acoustic wave at a second frequency, where the first frequency is different than the second frequency.

Additionally, or alternatively, the filter may include a controller operatively connected to the switch unit to selectively change the switch unit from the one position to the other position.

Additionally, or alternatively, the substrate may include a piezoelectric material.

Additionally, or alternatively, the resonator may include a piezoelectric material.

Additionally, or alternatively, the resonator may include an electrically conductive material.

Additionally, or alternatively, the filter may include one of a surface acoustic wave filter, a bulk acoustic wave filter, or a film bulk acoustic wave resonator filter.

Additionally, or alternatively, the switch may include one of a switch capacitor bank, a radio frequency (RF) switch, or a mechanical switch.

Additionally, or alternatively, the switch may be formed using complementary metal-oxide-semiconductor (CMOS) technology.

Additionally, or alternatively, the switch may be formed using one of Micro-Electro-Mechanical Systems (MEMS) technology, Pseudomorphic High Electron Mobility Transistors (PHEMT), or Gallium Arsenide (GaAs) switches.

Additionally, or alternatively, the first frequency may support Global System for Mobile communications (GSM) protocol, and the second frequency may support Long Term Evolution (LTE) protocol.

According to another implementation, a resonator for a tunable filer may include a first piezoelectric segment having an electrical input port, the first piezoelectric segment to propagate waves a first frequency in response to electrical input from the electrical input port; a second piezoelectric segment; and a switch to selectively join the second piezoelectric segment to the first piezoelectric segment, where the joining causes the first piezoelectric segment and the second piezoelectric segment to propagate waves at a second frequency in response to electrical input from the electrical input port, where the first frequency is different than the second frequency.

Additionally, or alternatively, the resonator may include a controller operatively connected to the switch unit to selectively change the switch unit from the one position to the other position.

Additionally, or alternatively, the resonator may include a piezoelectric material.

Additionally, or alternatively, the resonator may include an electrically conductive material.

Additionally, or alternatively, the switch may include one of a switch capacitor bank, an RF switch, or a mechanical switch.

Additionally, or alternatively, the switch may be formed using CMOS technology.

Additionally, or alternatively, the switch may be formed using MEMS technology.

According to yet another implementation, a tunable filter for a mobile terminal may include means for generating acoustic waves, at a first frequency, from an electrically-conductive geometric structure through a substrate; means for altering the electrically-conductive geometric structure to generate acoustic waves, at a second frequency, through the substrate, where the first frequency is different than the second frequency; and means for returning the electrically-conductive geometric structure from the altered structure.

Additionally, or alternatively, the means for altering may include means for electrically coupling additional components to the electrically-conductive geometric structure.

Additionally, the tunable filter may include means for altering the electrically-conductive geometric structure to generate acoustic waves, at a third frequency, through the substrate, where the third frequency is different from the first frequency and the second frequency.

### BRIEF DESCRIPTION OF THE DRAWINGS

The accompanying drawings, which are incorporated in and constitute a part of this specification, illustrate one or more systems and/or methods described herein and, together with the description, explain these systems and/or methods. In the drawings:

FIG. 1 depicts a diagram of an exemplary network in which devices and/or methods described herein may be implemented;

FIG. 2 depicts a diagram of exemplary components of a mobile terminal illustrated in FIG. 1;

FIG. 3 depicts a diagram of exemplary components of a communication interface illustrated in FIG. 2;

FIGS. 4A and 4B depict diagrams of exemplary components of a tunable filter with switched acoustic wave resonator illustrated in FIG. 3 according to an implementation described herein; and

FIG. 5 depicts a diagram of exemplary components of a tunable filter with switched acoustic wave resonator illustrated in FIG. 3 according to another implementation described herein.

### DETAILED DESCRIPTION

The following detailed description refers to the accompanying drawings. The same reference numbers in different drawings may identify the same or similar elements. Also, the following detailed description does not limit the invention.

### Overview

Systems and/or methods described herein may provide a switch-enabled tunable resonator for a tunable filter. One or more switches may be included within the resonator to selectively activate/deactivate resonator segments. The activation/deactivation of the resonator segments can alter the effective physical layout of the resonator and, thus, vary the frequency response of the filter. The tunable filter may be used within a multi-band mobile terminal to provide filtering for multiple frequency bands, thus eliminating the need to include individual filters for each frequency band.

A “mobile terminal,” as the term is used herein, is intended to be broadly interpreted to include a mobile communication device (e.g., a radiotelephone, a personal communications system (PCS) terminal that may combine a cellular radiotelephone with data processing, a facsimile, and data communications capabilities, a personal digital assistant (PDA) that can include a radiotelephone, pager, Internet/intranet access, web browser, organizer, camera, a Doppler receiver, and/or global positioning system (GPS) receiver, a GPS device, a telephone, a cellular phone, etc.); a laptop computer; a personal computer; a printer; a facsimile machine; a pager; a camera (e.g., a contemporary camera or a digital camera); a video camera (e.g., a camcorder); a gaming device; and/or any other device capable of wireless communications over more than one frequency band.

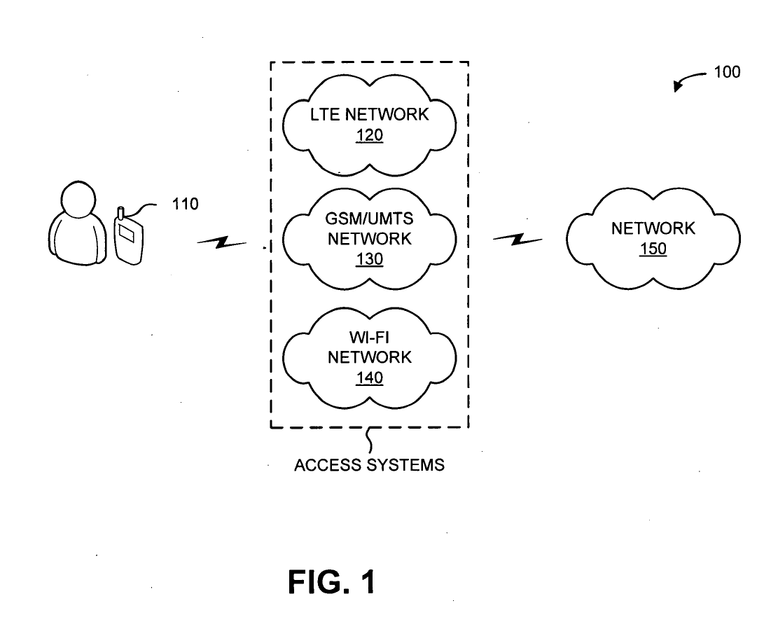

FIG. 1 depicts a diagram of an exemplary network 100 in which systems and/or methods described herein may be implemented. As shown, network 100 may include mobile terminal 110, a group of access systems (e.g., a Long Term Evolution (LTE) network 120, a Global System for Mobile communications (GSM)/ Universal Mobile Telecommunications System (UMTS) network 130, and a wireless local area network (Wi-Fi) network 140), and a network 150. Mobile terminal 110 may connect to one or more access systems via a wireless connection. The access systems and network 150 may interconnect via wired and/or wireless connections. A single mobile terminal 110, LTE network 120, GSM/UMTS network 130, Wi-Fi network 140, and network 150 have been illustrated in FIG. 1 for simplicity. In practice, there may be additional mobile terminals 110, networks 150, and/or access systems.

Mobile terminal 110 may include one or more devices capable of sending/receiving voice and/or data to/from network 150 via more than one of the access systems. For example, mobile terminal 110 may include a switch-enabled tunable resonator for a tunable filter to provide filtering for multiple frequency bands. Mobile terminal 110 may perform an access system selection (e.g., based on network preferences and/or geographic constraints), and may connect with a selected access system. In one implementation, mobile terminal 110 may operate interchangeably with LTE network 120, GSM/UMTS network 130, Wi-Fi network 140, and/or another type of access system.

LTE network 120 may include a wireless communication network that includes one or more devices (e.g., base stations) to which mobile terminal 110 may connect. LTE network 120 may include an evolved UMTS terrestrial radio access network (E-UTRAN) air interface. LTE network 120 may operate over one or more frequency bands, including, for example, 900, 1800, 2100, and/or 2600 MHz. LTE network 120 may include any IP network, such as a Worldwide Interoperability for Microwave Access (WiMAX) network, a WiFi network, or a wired network. The E-UTRAN interface may use Orthogonal Frequency-Division Multiple Access (OFDMA) for the downlink and a single carrier Frequency-Division Multiple Access (SC-FDMA) for the uplink and may employ multiple-input and multiple-output (MIMO) (e.g., with up to four antennas per base station).

GSM/UMTS network 130 may include a wireless communication network that includes one or more devices (e.g., base stations) to which mobile terminal 110 may connect. GSM/UMTS network 130 may include five different cell sizes (e.g., macro, micro, pico, femto, and umbrella cell sizes), where a coverage area of each cell may vary according to an implementation environment. GSM/UMTS network 130 may operate over one or more frequency bands, including, for example, 450, 800, 850, 900, 1800, 1900, and/or 2100 MHz. GSM/UMTS network 130 may transmit voice and/or data from or to mobile terminal 110 via an air interface (e.g., a W-CDMA air interface). GSM/UMTS network 130 may also include one or more devices that receive voice and/or data from mobile terminal 110 over an air interface.

Wi-Fi network 140 may include one or more devices (e.g., wireless routers) to which mobile terminal 110 may connect. Wi-Fi network 140 may use Institute of Electrical and Electronics Engineers (IEEE) 802.11 protocols to send data between mobile terminal 110 and another device via the wireless router. Wi-Fi network 140 may operate over one or more frequency bands, including, for example, 2400 MHz or 5000 MHz.

Network 150 may include a local area network (LAN), a wide area network (WAN), a metropolitan area network (MAN), an intranet, the Internet, a public land mobile network (PLMN), a telephone network, such as the PSTN or a cellular telephone network, an IMS network, or a combination of networks. In one implementation, network 150 may provide voice services (e.g., voice over IP (VoIP) services) and/or data services (e.g., video streaming, music downloading, mobile television, gaming, etc.) to mobile terminal 110, via one or more of the access systems (e.g., via one of more of LTE network 120, GSM/UMTS network 130, and Wi-Fi network 140).

LTE network 120, GSM/UMTS network 130, and Wi-Fi network 140 are exemplary access systems with multiple and/or different frequencies. Although FIG. 1 shows exemplary access systems of network 100, in other implementations, network 100 may contain fewer, different, or additional access systems than depicted in FIG. 1.

### Exemplary Mobile Terminal Configuration

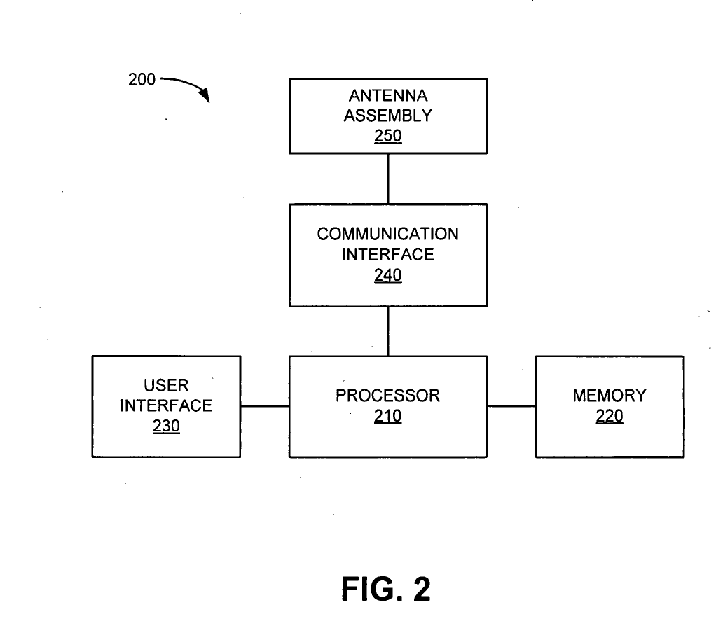

FIG. 2 depicts a diagram of exemplary components of a device 200 that may correspond to mobile terminal 110. As illustrated, device 200 may include a processing unit 210, memory 220, a user interface 230, a communication interface 240, and/or an antenna assembly 250.

Processing unit 210 may include one or more microprocessors, application-specific integrated circuits (ASICs), field-programmable gate arrays (FPGAs), or the like. Processing unit 210 may control operation of device 200 and its components. In one implementation, processing unit 210 may control operation of components of device 200 in a manner described herein.

Memory 220 may include a random access memory (RAM), a read-only memory (ROM), and/or another type of memory (e.g., flash memory) to store data and instructions that may be used by processing unit 210.

User interface 230 may include mechanisms for inputting information to device 200 and/or for outputting information from device 200. Examples of input and output mechanisms might include buttons (e.g., control buttons, keys of a keypad, a joystick, etc.) or a touch screen interface to permit data and control commands to be input into device 200; a speaker to receive electrical signals and output audio signals; a microphone to receive audio signals and output electrical signals; a display to output visual information (e.g., text input into device 200); a vibrator to cause device 200 to vibrate; etc.

Communication interface 240 may include, for example, a transmitter that may convert baseband signals from processing unit 210 to radio frequency (RF) signals and/or a receiver that may convert RF signals to baseband signals. Alternatively, communication interface 240 may include a transceiver to perform functions of both a transmitter and a receiver. Communication interface 240 may connect to antenna assembly 250 for transmission and/or reception of the RF signals.

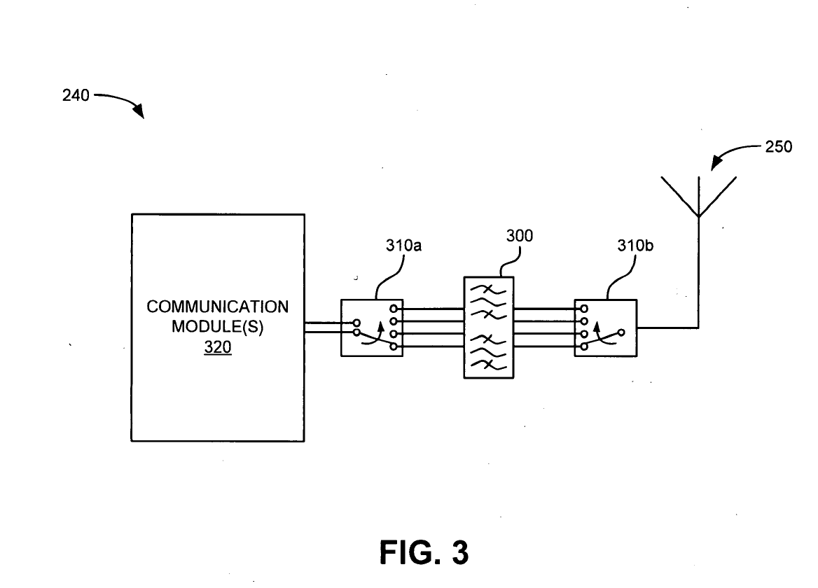

Communication interface 240 may also include one or more communications modules, such as a cellular communication module, a direct point-to-point connection module, and/or a WLAN module. With communication interface 240, a wireless terminal may communicate using one or more cellular communication protocols such as, for example, GSM communication, General Packet Radio Service (GPRS), enhanced data rates for GSM evolution (EDGE), code division multiple access (CDMA), wideband-CDMA, CDMA2000, Universal Mobile Telecommunications System (UMTS), Evolved Packet System (EPS comprising LTE), LTE Advanced and/or the like. As described further herein, communication interface 240 may include a tunable filter with a switch-enabled tunable resonator, for example, to simplify the architecture of mobile terminal 110. Communication interface 240 is described further in connection with, for example, FIG. 3.

Antenna assembly 250 may include one or more antennas to transmit and/or receive RF signals over the air. Antenna assembly 250 may, for example, receive RF signals from communication interface 240 and transmit them over the air, and receive RF signals over the air and provide them to communication interface 240. In one implementation, for example, communication interface 240 may communicate with other devices via an access system (e.g., LTE network 120, GSM/UMTS network 130, and/or Wi-Fi network 140).

Device 200 may perform certain operations described herein in response to processing unit 210 executing software instructions of an application contained in a computer-readable medium, such as memory 220. A computer-readable medium may be defined as a physical or logical memory device. A logical memory device may include memory space within a single physical memory device or spread across multiple physical memory devices. The software instructions may be read into memory 220 from another computer-readable medium or from another device via communication interface 240. The software instructions contained in memory 220 may cause processing unit 210 to perform processes described herein. Alternatively, hardwired circuitry may be used in place of or in combination with software instructions to implement processes described herein. Thus, implementations described herein are not limited to any specific combination of hardware circuitry and software.

Although FIG. 2 shows exemplary components of device 200, in other implementations, device 200 may contain fewer, different, differently arranged, or additional components than depicted in FIG. 2. In still other implementations, one or more components of device 200 may perform one or more other tasks described as being performed by one or more other components of device 200.

### Exemplary Communication Interface

FIG. 3 depicts a diagram of exemplary components of a communication interface 240. Communication interface 240 may include a tunable filter 300 connected with antenna 250, switching elements 310a and 310b, and one or more communication modules 320. Antenna 250 may include features described above in connection with, for example, FIG. 2.

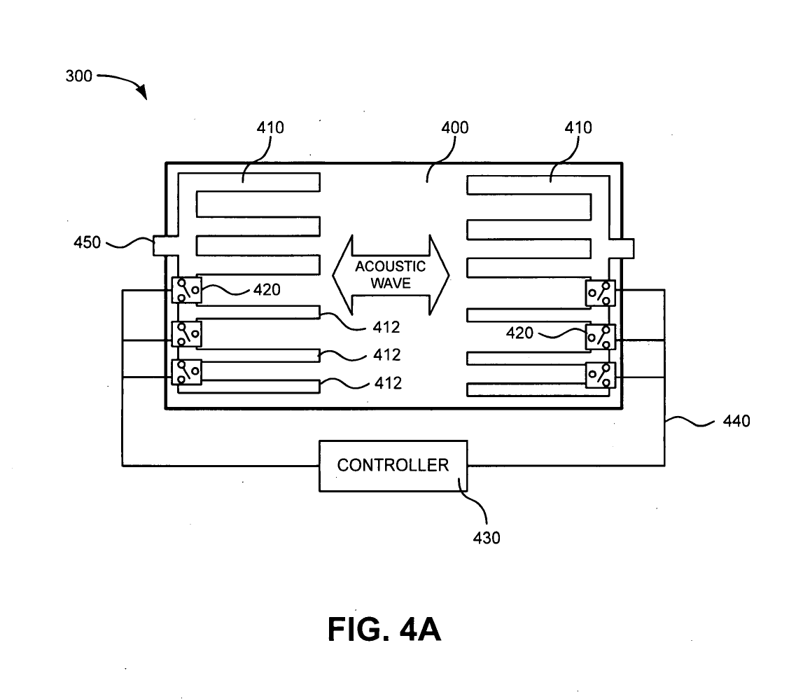

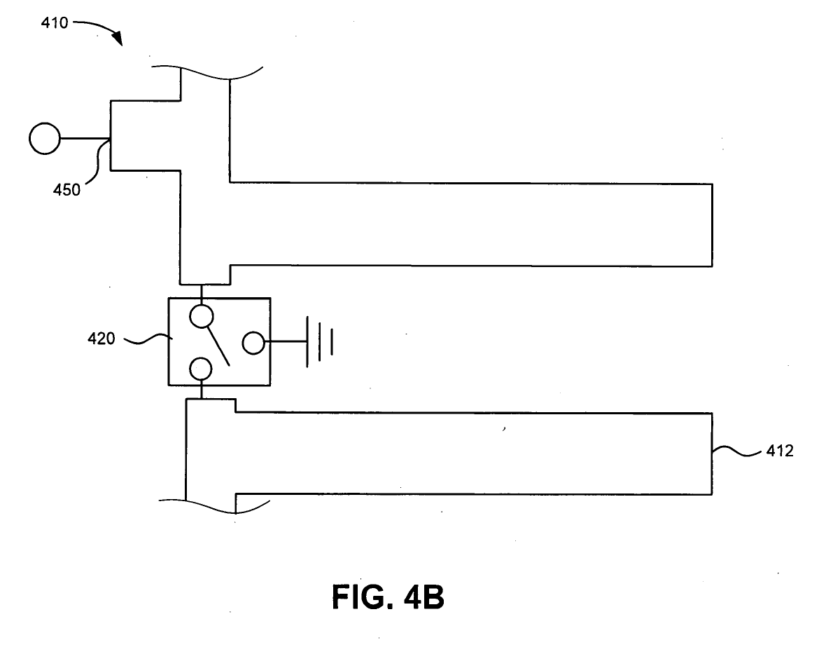

Tunable filter 300 may include an acoustic wave filter with a tunable resonator that may alter the effective physical properties of the resonator to achieve filtering of more than one frequency band. Tunable filter 300 may include a surface acoustic wave (SAW) filter, a bulk acoustic wave (BAW) filter, a film bulk acoustic wave resonator (FBAR) filter, or another type of acoustic wave filter. Tunable filter 300 is described further in connection with, for example, FIG. 4.

Switching elements 310a and 310b may include a device to selectively connect tunable filter 300 with one of communication modules 320 and antenna 250, respectively. Switching elements 310a and 310b may include, for example, a switch capacitor bank, an RF switch, or a mechanical switch. Communication module(s) 320 may include one or more sets of power amplifiers, additional filters, converters (e.g., up-converters, down-converters), and/or other components to provide multi-band communications for mobile terminal 110.

Although FIG. 3 shows exemplary components of communication interface 240, in other implementations, communication interface 240 may contain fewer, different, differently arranged, or additional components than depicted in FIG. 3. In still other implementations, one or more components of communication interface 240 may perform one or more other tasks described as being performed by one or more other components of communication interface 240.

### Exemplary Filters

FIGS. 4A and 4B provide diagrams of exemplary components of a tunable filter 300 with switched acoustic wave resonator according to one implementation. FIG. 4A provides a top view of tunable filter 300, and FIG. 4B provides an enlarged view of a portion of FIG. 4A. Referring collectively to FIGS. 4A and 4B, tunable filter 300 may include a substrate 400 onto which switched resonators 410 are applied. Resonators 410 may include multiple switching units 420 that are controlled by a controller 430 via leads 440.

Substrate 400 may include an acoustic material on and/or through which an acoustic wave may propagate. For example, substrate 400 may include one or more piezoelectric materials, such as quartz (SiO₂), lithium tantalite (LiTaO₃), and/or lithium niobate (LiNbO₃). In other implementations, substrate 400 may include other acoustic materials. In some implementations, substrate 400 may include multiple layers and/or multiple materials including both acoustic and non-acoustic materials. Substrate 400 may also include treated surfaces (e.g., rough, polished, etc.).

Resonators 410 may be mounted on substrate 400. Depending on the location of input signal, one resonator 410 may convert electric field energy into mechanical (e.g., acoustic) wave energy, and the other resonator 410 may convert the mechanical wave energy back into electric field energy. The construction and physical layout of resonators 410 may determine the frequency response of tunable filter 300. Resonators 410 may include one or more electrically conductive materials, such as aluminum or another metal. In another implementation, resonators 410 may include one or more piezoelectric materials, such as quartz (SiO₂), lithium tantalite (LiTaO₃), and/or lithium niobate (LiNbO₃). Resonators 410 may each be operatively connected to an electrical input/output at one or more locations, such as electrical port 450. Resonators 410 may include a number of segments 412 that may be selectively activated/deactivated through the use of switch units 420. The activation/deactivation of the resonator segments 412 may alter the effective physical layout of the resonator 410 and, thus, vary the frequency response of the filter 300.

Switch units 420 may include a mechanism to selectively engage one or more resonator segments 412 with one of resonators 410. Switch units 420 may include, for example, a switch capacitor bank, an RF switch, or a mechanical switch. In one implementation, switch units 420 may be implemented within filter 300 using complementary metal-oxide-semiconductor (CMOS) technology. In other implementations, switch units 420 may be implemented as Micro-Electro-Mechanical Systems (MEMS) switches, Pseudomorphic High Electron Mobility Transistors (PHEMT), Gallium Arsenide (GaAs) switches, or another switching technology. More particularly, the electronic components of switch units 420 may be fabricated using integrated circuit (IC) process sequences (e.g., CMOS), and the micromechanical components of switch units 420 may be fabricated using compatible micromachining processes that selectively etch away parts of the substrate or add new structural layers to form switch unit 420.

As shown in FIG. 4B, switch units 420 may provide a connection between a resonator segment 412 and a resonator 410. As shown in FIG. 4A, switch units 420 may also provide a connection between two resonator segments 412. When switch unit 420 is not providing a connection with a resonator segment 412, switch 420 may ground resonator 410. Switch units 420 may be arranged in series, as depicted in the arrangement of FIG. 4A. In other implementations, switch units 420 may be arranged in parallel to allow for greater variation and/or tuning options. In still other implementations, switch units 420 may be arranged in a combination of series and parallel arrangements.

Controller 430 may include hardware or a combination of hardware (e.g., processor 210) and software to selectively activate/deactivate switch units 420. Controller 430 may provide control signals to activate/deactivate switches 420 to maintain symmetry on either side of filter 300. In one implementation, controller 430 may receive an indication of a desired frequency band for mobile terminal 110 and selectively open and close switch units 420 to alter the effective geometry of resonator 410 and the resulting frequency of filter 300. Leads 440 may include a path that permits communication between controller 430 and switch units 420.

Although FIG. 4 shows exemplary components of tunable filter 300, in other implementations, tunable filter 300 may contain fewer, different, differently arranged, or additional components than depicted in FIG. 4. In still other implementations, one or more components of tunable filter 300 may perform one or more other tasks described as being performed by one or more other components of tunable filter 300.

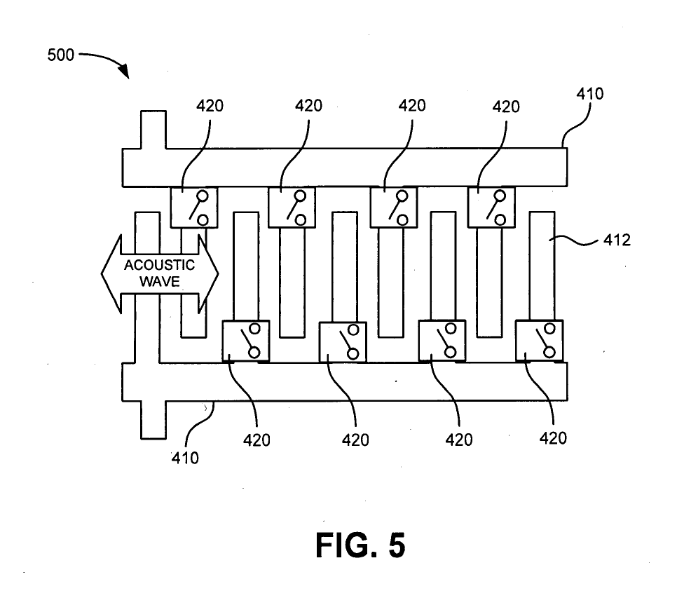

FIG. 5 depicts a different exemplary arrangement 500 of a switched acoustic wave resonator according to another implementation. Similar to FIGS. 4A and 4B, resonators 410 may include multiple switching units 420 that can be used to selectively engage and disengage resonator segments 412. Controller 430 and leads 440 are not shown in FIG. 5 for clarity. Switching units 420 may be positioned such that a disengaged resonator segment 412 will not affect communication with other resonator segments 412. Thus, switching units 420 may be used to alter the arrangement of active resonator segments 412 within each resonator 410.

While the arrangement of FIG. 5 provides another exemplary configuration of a switched acoustic wave resonator, other arrangements are possible. Depending on the length, width, and thickness of the various switched segments 412, numerous parts of a filter frequency response may be tuned. Thus, with enough switches, an acoustic wave filter, as described herein, may be capable of accomplishing channel filtering for virtually all available cellular and non-cellular channels, including, for example, various frequency bands for LTE, GSM, and wireless LANs.

### Conclusion

Systems and/or methods described herein may provide a filter for a mobile terminal that includes a substrate through which to propagate an acoustic wave, and a resonator on a surface of the substrate. The resonator may include at least a first segment and a second segment, the first segment being operatively connected to an electrical port. A switch unit may selectively connect the first segment and the second segment. When the switch unit is in one position (e.g., closed), the first segment and second segment may be connected and may generate, through the substrate, an acoustic wave at a first frequency. When the switch unit is in another position (e.g., open), the first segment and the second segment may be separated and may generate, through the substrate, an acoustic wave at a second frequency. Multiple other segments and switches may be included to form other geometric resonator structures that may propagate acoustic waves at other frequencies.

The foregoing description of implementations provides illustration and description, but is not intended to be exhaustive or to limit the invention to the precise form disclosed. Modifications and variations are possible in light of the above teachings or may be acquired from practice of the invention.

It will be apparent that aspects, as described above, may be implemented in many different forms of software, firmware, and hardware in the implementations illustrated in the figures. The actual software code or specialized control hardware used to implement these aspects should not be construed as limiting. Thus, the operation and behavior of the aspects were described without reference to the specific software code--it being understood that software and control hardware could be designed to implement the aspects based on the description herein.

Even though particular combinations of features are recited in the claims and/or disclosed in the specification, these combinations are not intended to limit the disclosure of the invention. In fact, many of these features may be combined in ways not specifically recited in the claims and/or disclosed in the specification.

No element, block, or instruction used in the present application should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A filter for a mobile terminal, comprising:
a substrate through which to propagate an acoustic wave;
a resonator on a surface of the substrate, the resonator including a first segment and a second segment, the first segment operatively connected to an electrical port; and
a switch unit, where the switch unit connects the first segment and the second segment when the switch unit is in one position, the connected first segment and second segment configured to generate, through the substrate, an acoustic wave at a first frequency, and where the switch unit separates the first segment and the second segment when the switch unit is in another position, the separated first segment configured to generate, through the substrate, an acoustic wave at a second frequency, where the first frequency is different than the second frequency.

2. The filter of claim 1, further comprising:
a controller operatively connected to the switch unit to selectively change the switch unit from the one position to the other position.

3. The filter of claim 1, where the substrate comprises a piezoelectric material.

4. The filter of claim 1, where the resonator comprises a piezoelectric material.

5. The filter of claim 1, where the resonator comprises an electrically conductive material.

6. The filter of claim 1, where the filter comprises one of:
a surface acoustic wave filter;
a bulk acoustic wave filter; or
a film bulk acoustic wave resonator filter.

7. The filter of claim 1, where the switch comprises one of:
a switch capacitor bank;
a radio frequency (RF) switch; or
a mechanical switch.

8. The filter of claim 1, where the switch is formed using complementary metal-oxide-semiconductor (CMOS) technology.

9. The filter of claim 1, where the switch is formed using one of Micro-Electro-Mechanical Systems (MEMS) technology, Pseudomorphic High Electron Mobility Transistors (PHEMT), or Gallium Arsenide (GaAs) switches.

10. The filter of claim 1, where the first frequency supports Global System for Mobile communications (GSM) protocol, and where the second frequency supports Long Term Evolution (LTE) protocol.

11. A resonator for a tunable filer, comprising:
a first piezoelectric segment having an electrical input port, the first piezoelectric segment to propagate waves at a first frequency in response to electrical input from the electrical input port;
a second piezoelectric segment; and
a switch to selectively join the second piezoelectric segment to the first piezoelectric segment, where the joining causes the first piezoelectric segment and the second piezoelectric segment to propagate waves at a second frequency in response to electrical input from the electrical input port, where the first frequency is different than the second frequency.

12. The resonator of claim 11, further comprising:
a controller operatively connected to the switch unit to selectively change the switch unit from the one position to the other position.

13. The resonator of claim 11, where the resonator comprises a piezoelectric material.

14. The resonator of claim 11, where the resonator comprises an electrically conductive material.

15. The resonator of claim 11, where the switch comprises one of:
a switch capacitor bank;
a radio frequency (RF) switch; or
a mechanical switch.

16. The resonator of claim 11, where the switch is formed using complementary metal-oxide-semiconductor (CMOS) technology.

17. The resonator of claim 11, where the switch is formed using Micro-Electro-Mechanical Systems (MEMS) technology.

18. A tunable filter for a mobile terminal, comprising:
means for generating acoustic waves, at a first frequency, from an electrically-conductive geometric structure through a substrate;
means for altering the electrically-conductive geometric structure to generate acoustic waves, at a second frequency, through the substrate, where the first frequency is different than the second frequency; and
means for returning the electrically-conductive geometric structure from the altered structure.

19. The tunable filter of claim 18, where the means for altering includes means for electrically coupling additional components to the electrically-conductive geometric structure.

20. The tunable filter of claim 18, further comprising:
means for altering the electrically-conductive geometric structure to generate acoustic waves, at a third frequency, through the substrate, where the third frequency is different from the first frequency and the second frequency.
